(19) United States
(12) Patent Application Publication
(10) Pub. No.: US 2009/0071707 A1
(43) Pub. Date: Mar. 19, 2009

(54) Multilayer substrate with interconnection vias and method of manufacturing the same

(75) Inventors: Kimitaka Endo, Yokohama (JP); Philip Damberg, Cupertino, CA (US); Craig S. Mitchell, San Jose, CA (US); Sean Moran, Burlingame, CA (US); Christopher Wade, Los Gatos, CA (US); Belgacem Haba, Saratoga, CA (US); John Riley, Dallas, TX (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 12/228,537

(22) Filed: Aug. 13, 2008

Related U.S. Application Data
(60) Provisional application No. 60/964,916, filed on Aug. 15, 2007.

(51) Int. Cl. H05K 1/11; C25D 5/02

(52) U.S. Cl. 174/266; 205/131

(57) ABSTRACT

A method is provided for manufacturing a multilayer substrate. An insulating layer can have a hole overlying a patterned second metal layer. In turn, the second metal layer can overlie a first metal layer. A third metal layer can be electroplated onto the patterned second metal layer within the hole, the third metal layer extending from the second metal layer onto a wall of the hole. When plating the third metal layer, the first and second metal layers can function as a conductive commoning element.

### CROSS REFERENCE TO RELATED APPLICATION

This application claims the benefit of the filing date of U.S. Provisional Application No. 60/964,916 filed Aug. 15, 2007, the disclosure of which is hereby incorporated by reference herein.

### FIELD OF THE INVENTION

The subject matter of the present application relates to a multi-layer substrate, wiring board, or interconnection element, including vias that provide electrical interconnection between layers, for example, and a method of manufacturing such multilayer substrate, wiring board, or interconnection element.

### BACKGROUND OF THE INVENTION

Multilayer substrates are commonly used for interconnection, support, or integration of electronic devices such as microchips, SAW filters, etc., which may be pre-packaged or may be combined with the multilayer substrate in a package. The multilayer substrates include conductive layers with traces, wirings, pads, etc, on both sides of an insulating layer. The conductive layers may be electrically interconnected through the insulating layer to electrically connect signal paths, ground planes, etc or for mechanical connection for improved thermal conduction, improved adherence of the individual layers, etc. Such interconnection is usually done with conductive features called vias. The manufacturing of these substrates has become increasingly complicated in recent years. This is due to the use of electronic devices that are made with smaller footprints and are made for high-density packaging. In addition, communication in electronic devices is becoming increasingly fast. Therefore, communication paths have to be made suitable for high-speed communication. The increase in communication speed requires improved electrical conduction between layers of a multilayer substrate. In addition, smaller sized conduction paths can reduce capacitive and inductive behavior of the conduction paths.

In the case of a multilayer substrate, conductive and non-conductive layers alternate each other. The non-conductive layers are usually made of a dielectric layer that insulates two conducting layers that are arranged on each side of the dielectric layer. The conductive layers are usually patterned to form conductive features such as traces, connections, pads, terminals, etc. For an electrical interconnection of the conductive layers with each other, vias are manufactured into the dielectric layer. Signals, power supply lines, thermal conduction etc. can thereby go from a trace formed from one conductive layer to a trace of the other conductive layer on opposite sides of the dielectric layer. Preferably such vias are made very small to allow a high density of traces, pads, and other conductive features of the multilayer substrate.

Different methods of manufacturing such vias for interconnecting conductive layers have been proposed. In one background method, a patterned circuit layer is covered with a dielectric layer. Via holes are then formed into the dielectric layer that will expose portions of the patterned circuit layer. The via holes are then filled with solder material that adheres to the patterned circuit layer to form an interconnection via. Subsequently, another metal layer is laminated over the solder material that will form the vias, and over the upper surface of the dielectric layer. The laminated metal layer is then brought into electrical connection of the vias made of solder a step of heating to wet the solder of adhesion.

Another method of manufacturing vias in a multilayer substrate was described in the U.S. Pat. No. 5,956,843. In this patent, holes for vias are formed at predetermined positions in a first insulating layer. A first thin metal layer is then deposited into said via holes. Such deposition is done by an electroless CAP plating. The first metal layer is also deposited at areas on top of the insulating layer adjacent to the via hole. A substantial portion of the via hole is thereby still void of any material. Subsequently, the remaining portions of the via holes that are void are filled with a copper paste. The upper surfaces of the first metal layer and the insulating layer are then smoothed after the filling with copper paste by grinding. Additional insulating layers, vias, and metal layers may be added subsequently, to add additional layers to the multilayer substrate.

Another method of manufacturing such vias was described in the U.S. Pat. No. 6,884,709. In this method, a first support layer is prepared with a plurality of posts that project from the surfaces the first support layer. In addition, a second support layer is prepared with an insulating film for interlayer insulation that was deposited on a surface of the second support layer. Holes corresponding to the projecting posts of the first layer are then formed in the insulating film that covers the second layer. In a next step, the first and second support layers are brought face-to-face with each other, so that the projecting posts are aligned with the holes formed in the insulating film. Next, the first and second layers are pressed into each other so as to make the insulating film be penetrated with the projecting posts. Then, the first and second support layers are removed, and an insulating film remains with the posts traversing the insulating film at locations of the holes. The insulating film can then be laminated with metal layers from both sides so as to form two patterned wiring layers that are interconnected with the posts.

Despite all the advancements in technology for manufacturing multilayer substrates, still further improvements in making such substrates would be desirable.

### SUMMARY OF THE INVENTION

In accordance with an aspect of the invention, a method is provided for manufacturing a multilayer substrate. In such method, an insulating layer can have a hole overlying a patterned second metal layer. In turn, the second metal layer can overlie a first metal layer. A third metal layer can be electroplated onto the patterned second metal layer within the hole, the third metal layer extending from the second metal layer onto a wall of the hole. When plating the third metal layer, the first and second metal layers can function as a conductive commoning element.

In accordance with another aspect of the invention, a method is provided for manufacturing a multilayer substrate. In such method, a via-hole can be formed which extends through a first insulating layer to expose a first patterned metal layer. The first patterned metal layer may overlie and be in conductive communication with a second metal layer. The via hole can then be filled substantially with metal to form a via by electroplating such that the via is in conductive communication with the first patterned metal layer. A third metal layer can be formed at least on top of and in conductive communication with the via. When electroplating the via, the second metal layer can function as a conductive path for an electroplating current.

In accordance with an aspect of the invention, a method is provided for manufacturing a conductive via at least partially within an opening of a non-conductive layer overlying a metallic pad, in which the metallic pad overlies and is in conductive communication with a base metal layer. In such method, the opening can be filled substantially with metal to form a via by electroplating, such that the via is in conductive communication with the metallic pad. When filling the opening by electroplating, the base metal layer and the metallic pad can conduct an electroplating current.

In accordance with another aspect of the invention, a multilayer wiring element is provided which can include a first patterned metal layer having an upper surface and a lower surface remote from the upper surface. An insulating layer can overlie the upper surface of the first patterned metal layer, with the insulating layer having a hole exposing the first patterned metal layer. A plated second metal layer can extend upwardly along a wall of the hole from the first patterned metal layer. A third metal layer can overlie an upper surface of the insulating layer and be in conductive communication with the second metal layer. A metallic post may protrude from the lower surface of the first patterned metal layer.

### BRIEF DESCRIPTION OF THE DRAWINGS

These and other features, aspects and advantages of the present invention will become better understood with regard to the following description, appended claims and accompanying drawings where:

FIGS. 1a-1j are diagrammatic cross-sectional views of the stages in method in accordance with a first embodiment of the present invention;

FIG. 1k-1L illustrate stages in a method in accordance with a variation of the first embodiment;

FIGS. 2a-e are depicting diagrammatic cross-sectional views of stages in method in accordance with the first embodiment of the present invention;

FIG. 3 shows a diagrammatic cross-sectional view of a multilayer substrate according to another embodiment of the present invention;

FIG. 4 shows a diagrammatic cross-sectional view of a multilayer substrate according to yet another embodiment of the present invention;

FIG. 5 shows a diagrammatic cross-sectional view of a multilayer substrate according to the present invention used as a interconnection board for a flip-chip microelectronic device;

FIG. 6 shows a diagrammatic cross-sectional view of a multilayer substrate according to the present invention used as a interconnection board for another type of flip-chip microelectronic device; and

FIG. 7 shows a diagrammatic cross-sectional view of a multilayer substrate according to the present invention used as an interconnection board for a wire bonded microelectronic device.

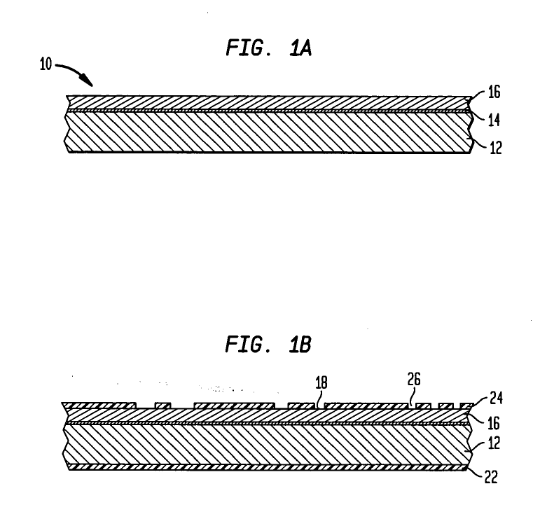

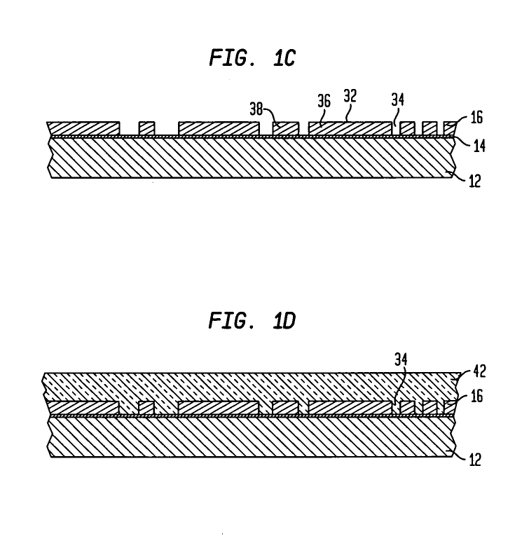

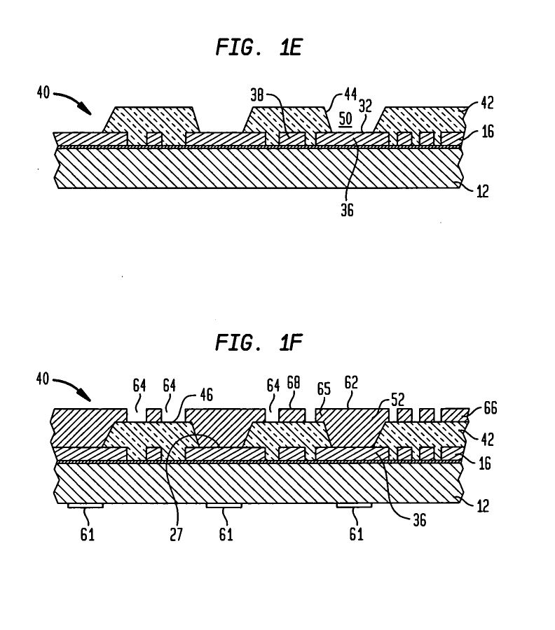

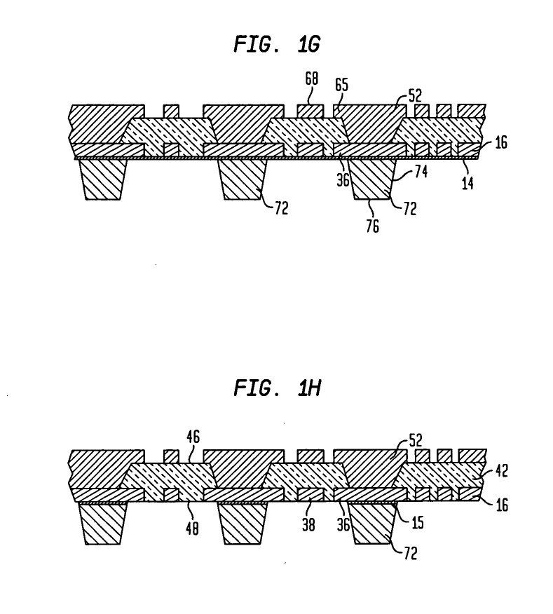

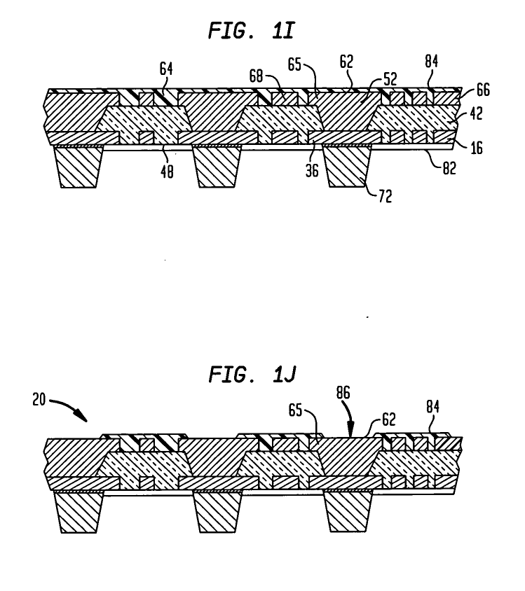

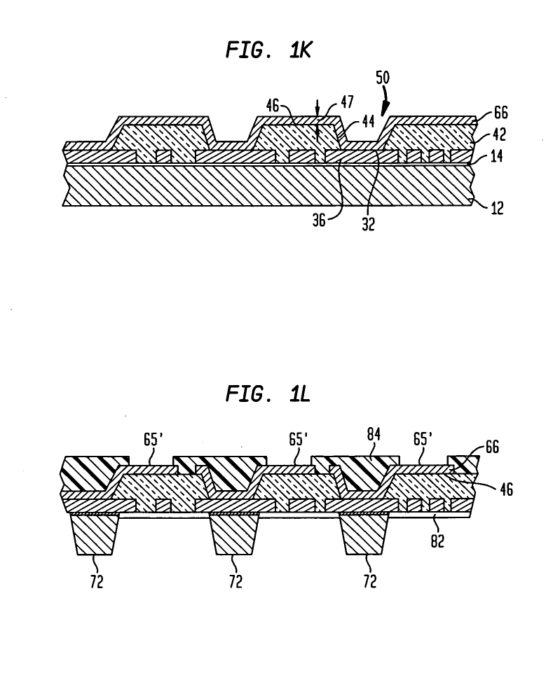

The above FIGS. 1-7 are for explanatory purposes only and show diagrammatic or schematic views of stages in methods as well as embodiments of the invention. These representations may not correspond to real proportions of the elements of a multilayer substrate and the steps in a method of manufacturing such a substrate. Many different dimensions and proportions are also possible.

### DETAILED DESCRIPTION

In a method of manufacturing a multilayer substrate according to a first embodiment of the present invention, a composite metal sheet 10 is provided (FIG. 1a). As shown in FIG. 1a, the composite metal sheet 10 may include an first upper metal layer 16 and a second bottom metal layer 12 formed from a readily etchable metal such as copper, and very thin etch-stop layer 14 formed from a different metal, for example nickel, at the interfaces between the etchable first and second layers 16, 12. As used in this disclosure, terms such as “upwardly,” “upper,” “top,” “downwardly,” “lower,” “bottom,” “vertically,” and “horizontally” should be understood as referring to the frame of reference of the element specified and need not conform to the normal gravitation frame of reference.

Moreover, as used in this disclosure, a terminal or other conductive feature is regarded as “exposed at” a surface of a dielectric element or solder mask layer where the terminal is arranged so that all or part of the conductive feature can be seen by looking at such surface. Thus, a conductive feature which is exposed at a surface of a dielectric element or solder mask layer may project from such surface; may be flush with such surface; or may be recessed from such surface and exposed through an opening extending entirely or partially through the dielectric element.

A mask 24 is formed over the first metal layer 16 which exposes portions 26 of the first metal layer 16. The second metal layer 12 may also be covered by a mask layer 22 so that the subsequent etching process does not attack the bottom layer 12. (FIG. 1b.) Subsequently, the first metal layer 16 is etched from the upper surface 18 (FIG. 1c) to leave conductive features such as connection pads 36 and wiring traces 38 from the first layer 16. Other metallic features may be formed from the first layer 16 by this step of etching. The etching is performed so as to remove the first metal layer 16 entirely at etch portions 34, until the etch stop layer 14 is exposed. A copper etch that does not attack the etch stop layer 14 may be used. In the case the etch stop layer 14 is made of nickel, ammonium or an ammonium chloride based etchant can be used. The remaining portions of the mask layers 24 and 22 are subsequently removed.

In a next step, the upper surfaces of the etch stop layer 14 and the patterned first layer 16 are covered with a dielectric layer 42 or other insulating material (FIG. 1d) Insulating layer 42 may be produced, for example, by spin-coating using a flowable dielectric material such as an uncured polyimide. It is also possible that a dielectric layer 42 is pressed onto the first layer 16. Thereby, the portions 34 between side walls of the wiring traces 38 and connection pads 36 can be filled with the dielectric layer 42.

As shown in FIG. 1e, via holes 50 are made into the dielectric layer 42 of the unfinished multilayer substrate 40, so as to expose at least a portion of the upper surface 32 of pad 36. At least some of traces 38 will remain covered by the dielectric layer 42. Via holes 50 can have slanted side walls 44 with a decreasing diameter towards the upper surfaces 32 of pads 36. (FIG. 1e) The via holes 50 can be made by laser drill, micro-machining techniques, etc. It is also possible to form the holes by an etching process, if the portions of the dielectric layer 42 that will remain are covered with a mask.

As illustrated in FIG. 1f, via holes 50 are filled with a metal material so as to form metal fills or metal vias 52. The vias 52 are built up from the upper surface 32 of the pad 36 that is exposed by hole 52. In such a process, first a metallic barrier layer (not shown) can be deposited on portions of the upper surface 46 of dielectric layer 42, and within holes 50. The metallic barrier layer may be deposited by Physical Vapor Deposition (PVD) (sputtering) or a Chemical Vapor Deposition (CVD) process, lamination process, or by an electroless plating method. Once the metallic barrier layer is deposited, the third metal layer 66 with pads 65 and traces 68 is preferably built up by an electroplating process on top of the barrier layer to a desired thickness. The upper surfaces of the barrier layer serves as electrodes-cathodes for the electroplating. The barrier layer will be in electrical connection with vias 52, pads 36 and second metal layer 12 by the etch stop layer 14. Such electric connection allows the electroplating current flow through the second metal layer when plating the vias and layer 66.

Thereafter, the filling of the holes 50 can be done via electroplating, where the bottom layer 12 and etch-stop layer 14, when present, are used as a conductor for the electroplating current for all pads 36 that are exposed within the via holes 50. The upper surface 32 of pads 36 will be in contact with the electrolyte of the plating bath, and thereby will form the cathode for electroplating. Since the bottom layer 12 is in electrical contact with the upper surfaces 32 of pads 36 by the etch stop layer 14, metal ions can be deposited into holes 50 so as to fill the holes 50 with metal. Multiple vias 52 can thereby be simultaneously formed by a plating process. The electroplating fills holes 50 substantially with metal to build up vias 52 made of a homogenous metal that are in electrical communication with the pads 36, the etch stop layer 14, and the second layer 12. The filling of holes 50 can be continued until the hole 50 is substantially or completely filled.

When filling the via holes, a third metal layer 66 is formed on the exposed surface 46 of the insulating layer 42. After deposition of the third metal layer 66, layer 66 can be patterned, such as by photolithography to form traces 68 and pads 65. The length D₁ of the vias 52 may be longer than the thickness D₂ of the third metal layer 66 in a particular example of the process. In another example, the thickness of layer 66 is greater. Next, it is also possible to deposit a protective layer (not shown) on top of the upper surface of the third metal layer, for example a thin gold or silver layer for protection purposes.

At this stage in the method of manufacturing a multilayer substrate, it is possible to add additional layers. For example, an additional step of adding a next dielectric layer can be performed as described above with reference to FIG. 1d, and then an additional step of making a next series of via holes into the dielectric layer can be done similar to that shown in FIG. 1e. Furthermore, an additional step of filling the next series of holes to form second vias and a patterned metal layer on top of the dielectric layer may be performed. (FIG. 1f.) In these steps, the second metal layer 12 can also be used as an electrode for an electroplating process, since the additional metal layers added will be in electrical communication with the second metal layer 12. These steps can be repeated until the desired number of layers are built up.

Next, after forming vias 52 and forming the third metal layer 66, the second metal layer 12 can be processed. A mask 61 (FIG. 1f) is applied to the exposed surface of the second metal layer 12. The mask 61 defines locations of protrusions 72 (FIG. 1g) that are formed when etching the second metal layer 12. The second metal layer is etched until the etch stop layer 14 is exposed at locations other than the protrusions 72. (FIG. 1g.) Protrusion 72 will be projecting from the lower surface of the etch stop layer 14. In the variant shown, the locations of the protrusions 72 correspond to the locations of the pads 36 of the first metal layer 16. Protrusions 72 are in electrical contact with pads 36, by the metallic etch stop layer 14. The protrusions 72 may be longitudinal posts having a bottom surface 76 configured to interconnect another circuit board, interconnection element, microelectronic device, etc. and may have slanted sidewalls 74, so that the protrusions 72 are tapered towards the lower end. Since the protrusions 72 are all formed from the same third metal layer 12, they have substantially the same length.

Since the etch stop layer 14 is still in electrical connection with all of the protrusions 72 and the pads 36, the etch-stop layer 14 is then removed at portions other than the portions covered by protrusion 72 (FIG. 1h). In case the etch-stop layer 14 is a nickel layer, the removal can be done with an etchant based on Sulfuric Acid and Hydrogen Peroxide. The lower surface 48 of the dielectric layer 42 is thereby not covered by a metallic layer, and the connection pads 36 and traces 38 are freed from electrical interconnection by the etch-stop layer 14. Between the protrusions 72 and the pads 36, a portion 15 of the etch stop layer 14 remains.

Next, the first metal layer 16 and the lower surface 48 of the dielectric layer 42 are covered with a first solder resist layer 82. In addition, the third metal layer 66 and the upper surface 46 of the dielectric layer 42 are preferably covered with a second solder resist layer 84. (FIG. 1i.) In the variant shown, the solder resist layer 84 is thick enough to fill the recesses between 64 traces 68 and pads 65, and to cover the upper surfaces 62 of the pads 65. Solder resist layers 82 and 84 may be formed by a curable resin that is spread out over the first or third metal layer 16, 66 in a liquid state, respectively, and is subsequently cured to form the solid first and second solder resist layers.

Subsequently, solder resist layer 84 is selectively removed from the upper surface thereof to form holes 86 to expose at least a portion of upper surfaces 62 of the pads 65. The removal may be done by an etching process, or by mechanical removal by grinding, laser drilling, etc. The exposed surfaces 62 of pad 65 form an upper terminal of the finished multilayer substrate 20. (FIG. 1j.) In the variant shown, the width D₃ of hole 86 exposing the upper surface 62 is narrower than the width D₄ of the pads 65. For example, the multilayer substrate 20 resulting from the manufacturing process can be used as an interconnection element for interconnection of a chip with a wiring board. While upper surfaces 62 of pads 65 can form terminal connections for solder balls to interconnect with an electronic device such as a semiconductor chip, the protrusions 72 can be used to contact with terminals of a wiring board.

It is possible to add a protective layer over the exposed surfaces 62 of pads 65. For example a thin gold or silver layer (not shown) may be deposited over these surfaces 62, so as to prevent corrosion. Such layers may also be deposited by an electroplating process, or by other metallic deposition processes.

In a variation of the above embodiment, a semi-additive electroplating process may be used. In this method, the vias 52 and the pads 65 and traces 68 of the third metal layer 66 are defined by the same build-up electroplating process. For this purpose, the portions of the upper surface 46 of the dielectric layer 42, the inner walls 44 of the holes 50, and the exposed surface 32 of pads 36 are covered with a thin metal layer or barrier layer for the electroplating process. The barrier layer may be made from a conductive metal such as copper, tantalum or titanium, etc. The portions 64 (FIG. f) above the dielectric layer, where metal layer 66 should not be deposited, are covered with a mask layer, that is a negative image of the patterns formed by pads 65 and traces 68 of the third conductive layer 66. Subsequently the electroplating process is started, and via holes 50 are filled with metal to form vias 52, and the third metal layer 66 is built up to form the portions of the barrier layer that are not covered by a mask. Thereby, pads 65, traces 68 and other metallic patterns of the third metal layer 66 may be created. Subsequently, the mask that was used to prevent build-up of metal at portions 64 can be removed, for example by a step of etching that does not attack the metal of the third metal layer 66.

Referring to FIG. 1k, in a variation of the foregoing-described embodiment, a third metal layer 66 is plated by a plating process to simultaneously coat exposed surfaces 32 of the pads 36, walls 44 of the holes 50 and a top surface 46 of the insulating layer 42. As described above, a relatively thin seed layer and a barrier layer may be deposited onto the insulating layer and to line the via holes before continuing by electroplating a thicker metal layer. As illustrated in FIG. 1k, the third metal layer only partially fills the via holes. Typically, the third metal layer 66 reaches a thickness 47 over the insulating layer 42 from a few tens of microns up to a few hundreds of microns, but does not completely fill the via holes 50.

FIG. 1L illustrates a stage of fabrication comparable to FIG. 1j after the third metal layer 66 has been patterned to form terminals or pads 65′ overlying a top surface 46 of the insulating layer 42, and after protrusions 72 are etched and solder masks 82 and 84 are formed.

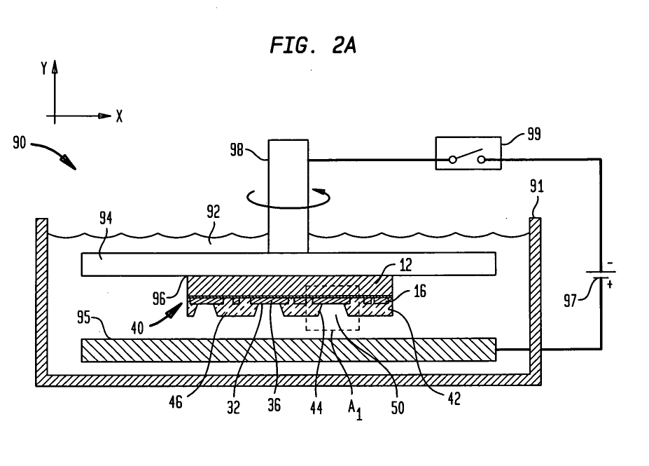

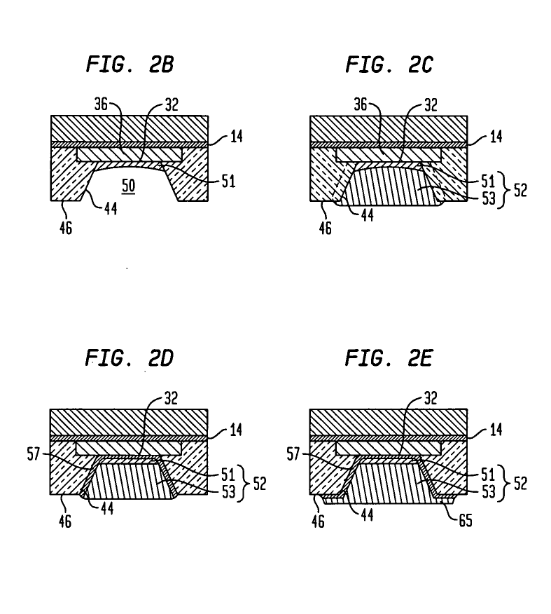

The stages of the method of manufacturing a multilayer substrate as shown with reference to FIG. 1f is shown in more detail with FIGS. 2a-2d. Stages of an electroplating process with an electroplating apparatus are shown, the process being configured to fill via holes 50 with metal to form vias 52 for the multilayer substrate 40. In addition, the third metal layer 66 may also be formed by the electroplating process. In FIGS. 2a-2d, the unfinished multilayer substrate 40 is shown rotated by 180° around a horizontal axis comparing to FIGS. 1a-k.

FIG. 2a shows a schematic representation of an electroplating apparatus 90 that can be used to perform electroplating of substrate 40. When using electroplating, metal layers can be deposited onto conductive surfaces, and holes may be filled with metal. For example, copper (Cu) films can be deposited onto other conductive surfaces. Other metals may be deposited in the electroplating process, such as nickel (Ni), gold (Au), gold-tin alloys, aluminum (Al), aluminum-copper alloys, tin, silver (Ag) etc. depending on the requirements of the plated layers. Electroplating apparatus 90 includes a DC power source 97 that is connected with the positive pole by a positive electrode (anode) 95 that is located inside an electrolyte solution 92 in a bulk deposition tub 91. The electrolyte solution is preferably a copper sulfate (CuSO₄). The negative pole of the power source 97 is connected with to a shaft 98. A chuck 94 is connected to the shaft 98, and the lower surface of the chuck 94 holds the unfinished multilayer substrate 40. It has to be noted that the substrate 40 shown is merely for representation purposes only. In reality, the unfinished substrate 40 will be much wider in x-direction and much thinner in y-direction. In the representation of FIG. 2a, the substrate 40 has merely three via holes 50. However, substrates having substantially different shapes and with many more via holes 50 may be electroplated in an electroplating apparatus as diagrammatically shown.

The shaft 98, chuck 94, second metal layer 12, and pads 36 of the first metal layer 16 of the unfinished multilayer substrate 40 are in electrical contact with each other, so that the pads 36 form the negative electrode (cathode) for the electroplating process. The surface 32 of the pads 36 of the first metal layer 16 will be in contact with the electrolyte solutions 92. The shaft 98 may be configured to move the chuck 94 up and down the y-axis to place the chuck 94 with the multilayer substrate 40 into and out of the electrolyte solution 92 of the deposition tub 91. In addition, the shaft 98 may be configured to rotate the chuck 94 during the electroplating process. The unfinished multilayer substrate 40 is temporarily attached to the lower surface of chuck 94 by a conductive adhesive 96 that provides homogenous electrical connection between both the lower surface of chuck 94, and the surface of second metal layer 12 of substrate 40. The other portions of chuck 94 may be coated by a non-conductive material such as Teflon, so as to avoid deposition of films on the chuck itself.

When the substrate 40 is held by chuck 94 into electrolyte solution 92, the DC power source 97 is put into electrical contact with the cathodes formed by the surfaces 32 of pads 36 by switch 99. Since switch 99 closes an electrical loop, a current will flow from through the electrolyte 92 from anode 95 to the cathode, formed by surfaces 32. At least a portion of this current will be positively charged metal ions, for example copper ions (Cu⁺⁺) which will be attracted and will adhere to the surfaces 32 of pads 36. Continuously a metal film will thereby be developed in the via holes 50.

FIG. 2b shows a diagrammatic cross-sectional close-up view of the area A₁ shown in FIG. 2a, after an initial step of electroplating has been performed. Surface 32 of pad 36 of the first metal layer 16 is covered with a thin film of metal 51, after a first step of electroplating. The first film of metal 51 in first via hole is also called seed layer. The seed layer 51 is deposited so as to form a good electrical and mechanical connection of via 52 with pad 36. The seed layer 51 may be thin. The seed layer is deposited by using a first current rate flowing through the electrolyte solution 92 for deposition of the metal layer. The DC power source 97 is variable so as to adapt the current rate of the electroplating process.

FIG. 2c shows a diagrammatic cross-sectional close-up view of the area A₁ shown in FIG. 2a, after an additional step of electroplating has been performed. After the seed layer 51 is deposited, a bulk filling layer 53 is deposited by electroplating, so as to form via 52. The electroplating of the bulk filling layer is performed at with a second current rate that is different from the first current rate. The first current rate is configured so as to have a good adherence of the seed layer 51 to the pad 36, to improve electrical resistance of the transition between the two layers 36, 51. The second current rate of the electroplating process is configured to deposit metal rapidly into hole 50, so as the form the bulk filling layer 53 in a short period of time. Preferably, the bulk filling layer 53 is deposited in a way to fill the remaining portions of the hole as fast as possible and at the same time providing a homogenous fill without any voids in hole 50. In the variant shown, the bulk filling layer 53 is deposited until inner walls 44 of hole 50, and edge portions of a surface 46 of the dielectric layer 42 adjacent to hole 50 are covered with the deposited metal. In the variant shown, no barrier layer was deposited onto the side walls 44 of the dielectric layer 42. Therefore, depending upon the characteristics of the deposited metal and the dielectric layer, the deposited metal may diffuse into portions 49 of the side walls 44 of dielectric layer 42 after the via hole 50 is filled with metal by electroplating. All the holes 50 of the unfinished multilayer substrate 40 with surface 32 of pad 32 that is in electrical contact with the second metal layer 12 can be processed simultaneously to deposit the seed layer 51 and subsequently the bulk filling layer 53, to form the via 52.

In a variant of filling the hole 50 by a electroplating with metal as shown in FIG. 2d, first a barrier layer 57 is deposited on the side walls 44 of via holes 50 and on the exposed surface 32 of the metal pad 36. The barrier layer 57 can prevent metal deposited by the electroplating from diffusing into the dielectric layer 42. In addition, since the barrier layer 57 is made of metal that will be in electrical contact with the exposed surface 32 of pad 36, it can help the electroplating process to fill via hole 50 from additional growth of the bulk filling layer 53 by the sidewalls 44 of hole 50. Such barrier layer 57 may be useful when the vias 52 are designed for very high speed communication signals, and diffusion of via metal into the dielectric layer would increase capacitive effects by increasing the overall outer surface of the vias 52. The barrier layer 57 can include a metal such as tantalum (Ta), tantalum nitride (TaN), titanium (Ti), or titanium nitride (TiN), for example, or a combination of such layers. The barrier layer can be formed by plating, for example.

As described above with reference to the fully-additive electroplating process, the barrier layer 57 may also extend to surface 46 of the dielectric layer 42, as shown with reference to FIG. 2e. In the case of the additive electroplating process, the portions of the barrier layer 57 that are formed on the surface 46 of dielectric layer have substantially a width D₄ to built-up the pad 65 of the third metal layer 66. While seed layer 51 was produced with a first electroplating current, via 52 and pad 65 of the third metal layer 66 may be built-up by a second, different electroplating current. Therefore, after depositing barrier layer 57 into the hole 50, a seed layer 51 can be deposited into hole 50, and subsequently a bulk filling layer 53 may be filled into the hole 50 so as to form via 52.

In a variant, the barrier layer 57 is deposited over the entire surface 46 of the dielectric layer 42 of substrate 40, on the side walls 44 of holes 50, and on the exposed surface 32 of pads 36, if the semi-additive electroplating process is used. Thereby, the holes 50 can be filled by electroplating, and after the filling of the holes 50, the third metal layer 66 can be built up over the vias 52 and the dielectric layer 42 (FIG. 1f.) The portions 64 where no third metal layer 66 should be deposited are covered by a mask. When the vias 52 and third metal layer 66 is deposited, the mask can be removed, and the barrier layer 57 that remains under the mask can also be removed.

It is also possible that the seed layer 51 be deposited by a CVD process or PVD (sputtering). In the PVD process, a plasma with positively charged ions are produced that are caused to collide with a metal target, to produce a shower of copper particles on the surface 32 and walls of the via holes. After depositing a seed layer by these alternative methods, the remaining portions of the hole 50 may be filled with an electroplating process to provide a bulk filling layer 53.

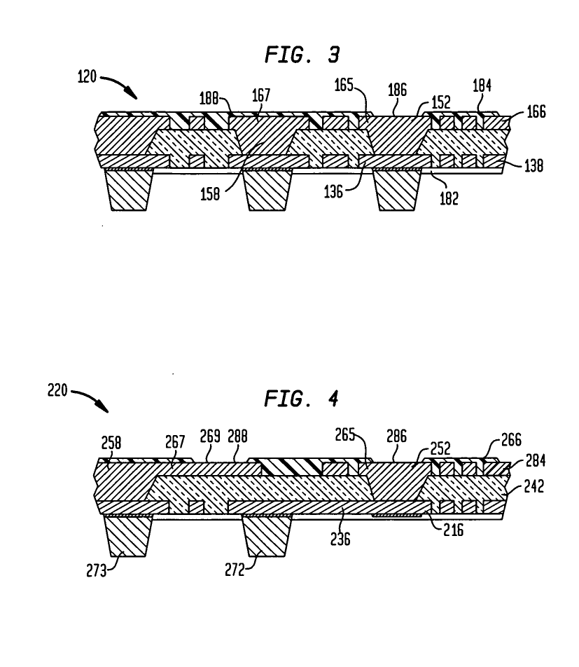

The resulting multilayer substrate 20 of the above described method is exemplary only. Other types of multilayer substrates may be manufactured with the same process. For example, another embodiment of the multilayer substrate 120 of the present invention is shown with respect to FIG. 3. The substrate 120 has upper and lower solder resist layers 184, 182 that have been etched to form holes 186, 188 to expose upper surfaces or lower surfaces of pads 165, 138 of the first and third metal layers 116, 166. Some pads 167 remain buried under the solder resist layer 184, to form buried vias 158 inside the substrate 120. Components can be attached or placed on the upper surface of the solder resist layer 184, without short-circuiting any of the pads 167.

FIG. 4 shows an additional embodiment of a multilayer substrate 220. In the variant shown, some of the vias 252 are not aligned in the same axis as the protrusions 272. The first metal layer 216 includes traces 236 that have longitudinal tabs that lead to a different location in the substrate 220, so that the vias 252 can be built up at a different location than the location of the protrusions 272. Pads 265 are placed on top of vias 252, and recess 286 in the solder resist layer 284 to expose at least a portion of the upper surface of pads 265. The variant with protrusion 272, trace 236, via 252 and pad 265 is useful to allow mechanical displacements of the protrusion 272 in vertical direction. Such vertical displacement of protrusions 272 may be desirable if the substrate 220 has to operate under thermal cycles with big temperature differences, or if the protrusions have to be placed on terminals of an external wiring board that is not perfectly planar. Such mechanical displacement of protrusions 272 is possible if the dielectric material of layer 242 is flexible, and the first metal layer 216 is thin enough to allow such movements. The third metal layer 266 that includes pad 265 may also form a trace in the form of a planar tab 267 that leads away from the location of via 258, so as to form a terminal 269 at the location of recess 288 of the solder resist layer 284. Thereby, via 258 is a buried. Such arrangement of protrusion 273, buried via 258, and terminal 269 can be used to increase the pitch size from the top surface of substrate 220, having a small pitch, to the bottom surface of the substrate 220, having a large pitch. Such arrangement of the conductive paths between the upper surface to the lower surface is called fan-out. It is also possible to provide a fan-in with the substrate 220, by having a larger pitch of on the upper surface of substrate 220, and a lower pitch on the bottom surface of substrate 220.

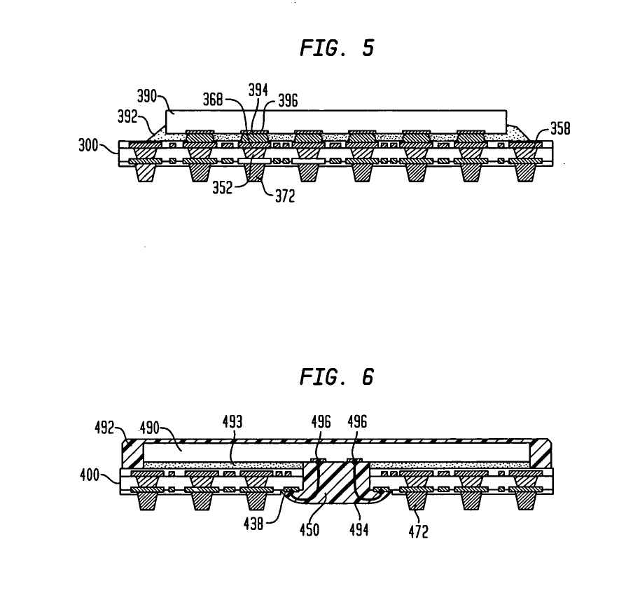

FIG. 5 shows a multilayer substrate 300 used as an interconnection board for a microelectronic device 390 that is mounted to the substrate by a flip-chip method. The microelectronic device 390 is attached to the upper surface of substrate 300 by an adhesive 392. The terminals 396 of device 390 are attached to the pads 368 of the third metal layer of the substrate 300 by solder balls 394. The terminals 396 of device 390, solder balls 394, pads 368, vias 352 and protrusions 372 are substantially aligned with each over, so as to provide a shortest possible conductive path to an external device or connection element that can be contacted to protrusions 371. This may be useful if the signals are that will use these paths are high-speed signals. On the edges of the multilayer substrate 300, buried vias 358 are arranged.

FIG. 6 shows a multilayer substrate 400 also used as an interconnection element for a flip-chip electronic device having terminals arranged in a middle portion of the lower surface. The substrate 400 includes a recess 450 substantially in the middle of the substrate 400. The device 490 has terminal contacts 496 arranged on a lower surface substantially in the middle of the device in two rows. The terminal contacts 496 are connected by bonding wires 494 to a row of terminal pads 438 that are arranged close to an edge of recess 450. The terminal pads 438 are interconnected with traces and vias to the protrusions 472 of substrate 400, so that the device 490 can be interconnected with an external device mounted to protrusions 472. The device 490 is flipped and the terminal rows 496 are aligned with the recess 450, so that the wires 494 can be bonded to terminal pads 438 of substrate 400. Device 490 is attached with an adhesive layer 493 to the upper surface of substrate 400. All the vias in substrate 400 are buried, since no connections pads are required on the upper surface of substrate 400. The upper portions of substrate 400 and device 490 are covered with a filler 492 such as an epoxy material. The filler 492 is also located inside recess 450, so that wires 494 are protected.

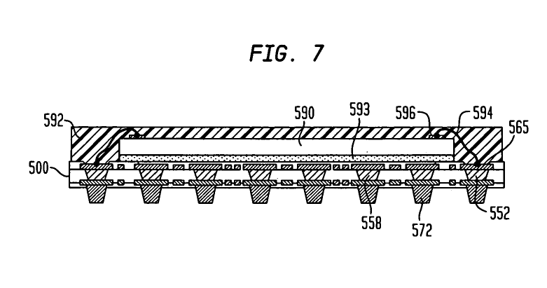

FIG. 7 shows multilayer substrate 500 used as an interconnection element for a wire-bonded microelectronic device 590. The device 590 is attached with its lower surface to the upper surface of the solder resist layer of substrate 500 by an adhesive layer 593. All the vias 558 underneath the device 590 are buried. Vias 552 arranged around the edge of substrate 500 have terminal pads 565 that can be wire-bonded by a wire 594 with the terminals 596 of the device 590. The upper surface of substrate 500 and device 590 is overmolded with a filler material 592, so that the wires 594 are protected from being dislodged from the terminals 596, 565.

Numerous variations and combinations of the features discussed above can be employed. For example, the number of vias, pads and traces, as well as layers of metal and dielectric material can be increased. Electronic devices that may be mounted or connected to multilayer substrates other than packaged chips may be for example, passive components, filters, etc. Further, bonding materials other than solder can be used. As these and other variations and combinations of the features discussed above can be utilized, the foregoing description of the preferred embodiment should be taken by way of illustration rather than by way of limitation of the invention.

1. A method of manufacturing a multilayer substrate, comprising:
electroplating a third metal layer onto an exposed patterned second metal layer within a hole in an insulating layer overlying the patterned second metal layer, the third metal layer extending from the second metal layer onto a wall of the hole, the second metal layer overlying a first metal layer, the first and second metal layers functioning as a conductive commoning element during the plating.

2. The method as claimed in claim 1, wherein the third metal layer extends from within the hole onto an upper surface of the insulating layer remote from the second metal layer.

3. The method as claimed in claim 2, further comprising patterning the third metal layer.

4. The method of manufacturing a multilayer substrate as claimed in claim 1, wherein said step of plating the third metal layer includes electrolessly plating a seed layer within the hole and electrolytically plating a metal layer onto the seed layer.

5. A method of manufacturing a multilayer substrate, comprising the steps of:
a) forming a via-hole through a first insulating layer to expose a first patterned metal layer, the first patterned metal layer overlying and in conductive communication with a second metal layer;
b) filling the via hole substantially with metal to form a via by electroplating, said via being in conductive communication with the first patterned metal layer; and
c) forming a third metal layer at least on top of said via, said third metal layer being in conductive communication with the via,
wherein in step (b), the second metal layer functions as a conductive path for an electroplating current.

6. The method of manufacturing a multilayer substrate as claimed in claim 5, further comprising a step of:
etching the second metal layer to form connection posts.

7. The method of manufacturing a multilayer substrate as claimed in claim 5, further comprising a step of:
etching the third metal layer to form a pattern into the third metal layer.

8. The method of manufacturing a multilayer substrate as claimed in claim 5, wherein said forming the third metal layer comprises:
forming the third metal layer by an electroplating process,
wherein in said forming said third metal layer, the second metal layer is used as conductive path for an electroplating current to build up the third metal layer.

9. The method of manufacturing a multilayer substrate as claimed in claim 5, wherein said step of filling the via hole and said step of forming the third metal layer are performed by a same step of electroplating.

10. The method of manufacturing a multilayer substrate as claimed in claim 5, further comprising:
selectively coating the third metal layer with a solder resists so as to form exposed metallic surfaces for interconnection on an upper surface of the third metal layer.

11. The method of manufacturing a multilayer substrate as claimed in claim 5, wherein at least one of said first patterned metal layer, said second metal layer, and said third metal layer is made of copper.

12. The method of manufacturing a multilayer substrate as claimed in claim 5, wherein said forming the third metal layer comprises:
forming the third metal layer by a fully-additive electroplating process.

13. The method of manufacturing a multilayer substrate as claimed in claim 5, wherein said forming the third metal layer comprises:
forming the third metal layer by a semi-additive electroplating process.

14. The method of manufacturing a multilayer substrate as claimed in claim 5, wherein said filling the via hole comprises:
depositing a barrier layer on an upper surface of the first patterned metal layer that is exposed by said via hole and on inner side walls of the via hole; and
filling a remaining portion of the via hole with metal by electroplating.

15. The method of manufacturing a multilayer substrate as claimed in claim 5, wherein
in said forming a third metal layer, the third metal layer is also formed on top of at least portions of said first insulating layer.

16. A method of manufacturing a conductive via at least partially within an opening of a non-conductive layer overlying a metallic pad, the metallic pad overlying and in conductive communication with a base metal layer, said method comprising the steps of:
filling the opening substantially with metal to form a via by electroplating, said via being in conductive communication with the metallic pad; and
wherein when filling the opening by electroplating said base metal layer and said metallic pad conduct an electroplating current.

17. The method of manufacturing a via as claimed in claim 16, further comprising a step of:
forming a metal layer at least on top of said via, said metal layer being in conductive communication with the via.

18. The method of manufacturing a via as claimed in claim 16, further comprising a step of:
depositing a barrier layer on top of portions of the metallic pad that are exposed by said opening and on side walls of the non-conductive layer of said opening before said step of filling the opening.

19. The method of manufacturing a via as claimed in claim 16, wherein said step of filling said opening further comprises:
depositing a seed layer by electroplating on top of portions of the metallic pad that are exposed by said opening.

20. A multilayer wiring element, comprising:
a first patterned metal layer having an upper surface and a lower surface remote from the upper surface;
an insulating layer overlying the upper surface of the first patterned metal layer, the insulating layer having a hole exposing the first patterned metal layer;
a plated second metal layer extending upwardly along a wall of the hole from the first patterned metal layer;
a third metal layer overlying an upper surface of the insulating layer in conductive communication with the second metal layer; and
a metallic post protruding from the lower surface of said first patterned metal layer.

21. The multilayer wiring element as claimed in claim 20 comprising:
a barrier layer disposed between the wall of the hole and the plated second metal layer.
